(19) United States
(12) Patent Application Publication
(10) Pub. No.: US 2024/0397795 A1
(43) Pub. Date: Nov. 28, 2024

(54) Display Panel and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Bo Zhang, Beijing (CN); Ying Liu, Beijing (CN); Hai Zheng, Beijing (CN); Ilsang Lee, Beijing (CN)

(21) Appl. No.: 18/695,202

(22) PCT Filed: Jul. 6, 2023
(86) PCT No.: PCT/CN2023/106161

§ 371 Date: Mar. 25, 2024

(30) Foreign Application Priority Data
Jul. 8, 2022 (CN) 202210800967.2

(51) Int. Cl. H10K 59/80; H10K 59/131; H10K 59/40

(52) U.S. Cl. CPC H10K 59/873; H10K 59/131; H10K 59/40

(57) ABSTRACT

A display panel includes a single-dam and a barrier structure. The single-dam is located on at least one side of a display area of the display panel and is arranged around at least part of the display area. A first groove is provided between the single-dam and the display area. At least one barrier structure is disposed between the first groove and the display area, and is arranged around at least part of the display area. The barrier structure includes a barrier wall and a second groove located between the barrier wall and the display area.

### CROSS-REFERENCE TO RELATED APPLICATIONS

This application is the United States national phase of International Patent Application No. PCT/CN2023/106161, filed Jul. 6, 2023, and claims priority to Chinese Patent Application No. 202210800967.2, filed Jul. 8, 2022, the disclosures of which are hereby incorporated by reference in their entireties.

### BACKGROUND OF THE INVENTION

### Field of the Invention

The present disclosure relates to the field of display technologies, and in particular, to a display panel and a display apparatus.

### Description of Related Art

At present, in the encapsulation process of organic light-emitting diode (OLED) displays, the encapsulation structure is made of the organic encapsulation material by using ink-jet printing (IJP) technology generally. The ink used to form the organic encapsulation structure has fluidity. In order to ensure the yield of IJP, it is particularly important to prevent ink overflow.

### SUMMARY OF THE INVENTION

In an aspect, a display panel is provided. The display panel includes a single-dam and at least one barrier structure. The single-dam is located on at least one side of a display area of the display panel and disposed around at least part of the display area. The single-dam and the display area are provided therebetween a first groove. The at least one barrier structure is located between the first groove and the display area and arranged around the at least part of the display area. Each barrier structure includes a barrier wall and a second groove that is located between the barrier wall and the display area.

In some embodiments, the at least one barrier structure includes a plurality of barrier structures. A plurality of second grooves and a plurality of barrier walls in the plurality of barrier structures are alternately arranged in a direction away from the display area.

In some embodiments, at least one barrier wall of the plurality of barrier walls is provided therein with at least one notch. A notch is communicated with two second grooves that are located on two sides of the notch, or communicated with the first groove and a second groove that are located on two sides of the notch.

In some embodiments, the display panel further includes a wiring area located on a same side of the display area as the single-dam, and the wiring area is provided therein with touch lines extending outward from the display area. A flatness of a portion of the at least one barrier structure in the wiring area is greater than a flatness of a portion of the at least one barrier structure outside the wiring area.

In some embodiments, at least one barrier wall of the at least one barrier structure is provided therein with at least one notch; the wiring area is located in a notch of the at least one barrier wall.

In some embodiments, the at least one barrier structure includes a plurality of barrier structures, all barrier walls in the plurality of barrier structures are each provided therein with a notch to communicate the first groove and all second grooves in the plurality of barrier structures, and the wiring area is located in notches provided in all the barrier walls.

In some embodiments, the at least one barrier structure includes a plurality of barrier structures, two adjacent barrier structures in the plurality of barrier structures include a first barrier structure and a second barrier structure; a barrier wall of the first barrier structure is provided with a notch in the wiring area, and a barrier wall of the second barrier structure is provided with no notch in the wiring area. The barrier wall in the second barrier structure includes a wall body and an extension wall. The wall body is arranged around the at least part of the display area. The extension wall is located in the wiring area and on a side of the wall body proximate to the barrier wall of the first barrier structure. The extension wall and the wall body are connected to each other to be a one-piece structure.

In some examples, in a direction perpendicular to an extension direction of the barrier wall, a sum of a dimension of the extension wall and a dimension of the wall body is substantially equal to a dimension of the single-dam.

In some embodiments, the extension wall passes through the notch disposed in the barrier wall in the first barrier structure and extends into a second groove in the first barrier structure.

In some embodiments, the barrier structure further includes a barrier platform, and the barrier platform is located in the wiring area, wherein a surface of the barrier platform away from a substrate of the display panel and a surface of the barrier wall away from the substrate constitute a substantially flat surface; the barrier platform is disposed in the second groove and divides the second groove into a first groove section and a second groove section. A barrier platform of a barrier structure in the at least one barrier structure is connected to a barrier wall located on at least one side of the barrier platform to form a one-piece structure.

In some embodiments, the at least one barrier structure includes a plurality of barrier structures; each second groove is provided therein with a barrier platform. In the wiring area, a plurality of barrier platforms and a plurality of barrier walls in the plurality of barrier structures together constitute a platform for carrying the touch lines.

In some embodiments, in an extension direction of the barrier wall, a barrier platform of the plurality of barrier platforms is provided therein with a plurality of third grooves spaced apart from each other. The touch lines include a plurality of first lines and a plurality of second lines. An orthographic projection of a first line on the substrate of the display panel overlaps with an orthographic projection of a third groove on the substrate; an orthographic projection of a second line on the substrate is located between orthographic projections of two third grooves, adjacent to each other in the extension direction of the barrier wall, on the substrate.

In some embodiments, in a direction perpendicular to the barrier wall, a barrier wall between two adjacent barrier platforms is provided therein with a through hole, and the through hole is communicated with two third grooves that are adjacent to each other in the direction perpendicular to the barrier wall. The orthographic projection of the first line on the substrate further overlaps with an orthographic projection of the through hole on the substrate.

In some embodiments, a dimension of the notch in an extending direction of the second groove is in a range of 200 μm to 500 μm, inclusive.

In some embodiments, for two adjacent barrier walls, a dimension, in a direction perpendicular to the display panel, of a barrier wall away from the display area is greater than the dimension, in the direction perpendicular to the display panel, of a barrier wall proximate to the display area.

In some embodiments, the display panel further includes a double-dam. The double-dam is located on at least one side of the display area, wherein the single-dam and the double-dam are located on different sides of the display area, and the double-dam includes a first dam body and a second dam body spaced apart from each other. In a connection region between the single-dam and the double-dam, the single-dam is connected to both the first dam body and the second dam body to form a one-piece structure.

In some embodiments, an edge of the barrier structure is spaced apart from the double-dam.

In some embodiments, the display panel further includes a fourth groove located on a side of the single-dam away from the display area.

In some embodiments, in a plane of the display panel, in a direction perpendicular to an extension direction of the second groove, a dimension of the first groove is greater than a dimension of the second groove.

In another aspect, a display apparatus is provided. The display apparatus includes the display panel as described in any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is an enlarged view of the region FD1 in an embodiment shown in FIG. 1;

FIG. 3 is a sectional view taken along the line H-H′ in FIG. 2;

FIGS. 4A to 4D are enlarged views of the region FD2 at different steps of manufacturing in an embodiment shown in FIG. 1;

FIG. 5 is a structural diagram of a connection region between a single-dam and a double-dam in a display panel, in accordance with some embodiments of the present disclosure;

FIG. 6 is a structural diagram of a display panel, in accordance with some embodiments;

FIG. 7A is a sectional view taken along the line A-A′ in FIG. 6;

FIG. 7B is a sectional view taken along the line B-B′ in FIG. 6;

FIG. 8 is a structural diagram of a wiring area in a display panel, in accordance with some embodiments;

FIG. 9 is a structural diagram of a wiring area in a display panel, in accordance with some embodiments;

FIG. 10 is a structural diagram of a wiring area in a display panel, in accordance with some embodiments;

FIG. 11 is a structural diagram of a wiring area in a display panel, in accordance with some embodiments;

FIG. 12 is a structural diagram of a wiring area in a display panel, in accordance with some embodiments;

FIG. 13 is a sectional view taken along the line L-L′ in FIG. 12;

FIG. 14 is a structural diagram of a wiring area in a display panel, in accordance with some embodiments;

FIG. 15 is a structural diagram of a wiring area in a display panel, in accordance with some embodiments; and

FIG. 16 is a sectional view taken along the line K-K′ in FIG. 15.

### DESCRIPTION OF THE INVENTION

The technical solutions in some embodiments of the present disclosure will be described clearly and completely with reference to the accompanying drawings; obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms such as “first” and “second” are used for descriptive purposes only and are not to be construed as indicating or implying the relative importance or implicitly indicating the number of indicated technical features. Thus, a feature defined by “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled,” “connected,” and derivatives thereof may be used. For example, the term “connected” may be used in the description of some embodiments to indicate that two or more elements are in direct physical or electrical contact with each other. For another example, the term “coupled” may be used in the description of some embodiments to indicate that two or more elements are in direct physical or electrical contact. However, the term “coupled” or “communicatively coupled” may also mean that two or more elements are not in direct contact with each other, but still cooperate or interact with each other. The embodiments disclosed herein are not necessarily limited to the contents herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes the following three combinations: only A, only B, and a combination of A and B.

As used herein, the term “if” is, optionally, construed as “when” or “in a case where” or “in response to determining that” or “in response to detecting,” depending on the context. Similarly, depending on the context, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event].”

The use of the phrase “applicable to” or “configured to” herein means an open and inclusive expression, which does not exclude devices that are applicable to or configured to perform additional tasks or steps.

Additionally, the use of the phase “based on” is meant to be open and inclusive, since a process, step, calculation or other action that is “based on” one or more of the stated conditions or values may, in practice, be based on additional conditions or value beyond those stated.

The term such as “about,” “substantially,” and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

In some examples, the display panel includes a display area and a non-display area, and the non-display area is provided therein with two circles of dam structure (Dam) surrounding the display area to prevent ink overflow after inkjet printing (IJP) is performed in the display area.

However, the inventors of the present disclosure found that providing two circles of Dam in the non-display area will increase the bezel size of the non-display area, which is not conducive to narrowing the bezel of the display panel.

In light of this, some embodiments of the present disclosure provide a display panel and a method for manufacturing the same and a display apparatus, which will be introduced respectively below.

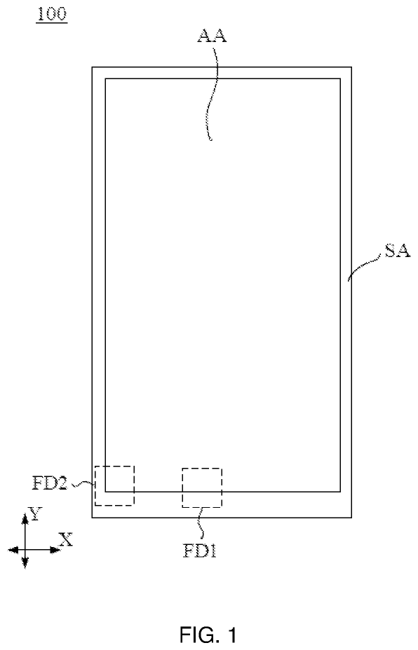

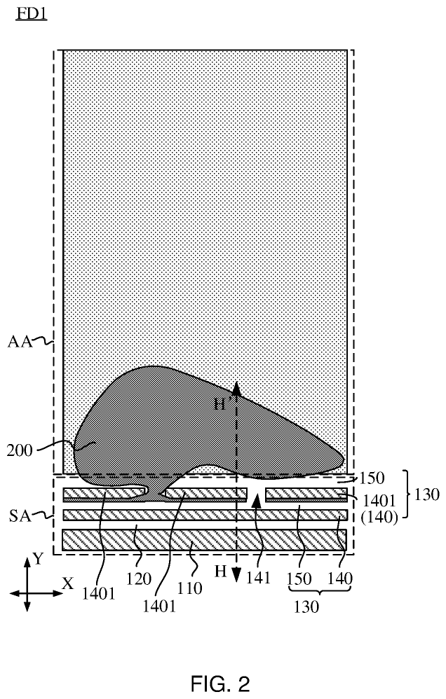

FIG. 1 is a top view of a display panel, in accordance with some embodiments. FIG. 2 is an enlarged view of the region FD1 in an embodiment shown in FIG. 1. As shown in FIGS. 1 and 2, the display panel 100 includes a display area AA for displaying an image and a non-display area SA in which no image is displayed, and the non-display area SA is located on at least one side of the display area AA. In some examples, the non-display area SA encircles the display area AA, or may be located outside the display area AA in at least one direction.

The display panel 100 in a plan view may be in a shape of rectangle, a circle, an ellipse, a rhombus, a trapezoid, a square or other shape depending to display requirements.

The display panel 100 may be applied to a variety of a display apparatuses, such as a tablet computer, a smart phone, a head-mounted display, an automobile navigation unit, a camera, a central information display (CID) provided in a vehicle, a wristwatch-type electronic apparatus or any other wearable device, a personal digital assistant (PDA), a portable multimedia player (PMP) and a game console, and a medium and large sized electronic apparatus such as a television, an external billboard, a monitor, a home appliance including a display screen, a personal computer and a laptop computer. The electronic device described above may represent an example for applying a display apparatus, and therefore, those skilled in the art may recognize that the display panel 100 may also be applied to other display apparatuses without departing from the spirit and scope of the present disclosure.

As shown in FIGS. 1 and 2, in the non-display area SA on at least one side of the display area AA, a single-dam 110 and a first groove 120 are included. The first groove 120 is located between the single-dam 110 and the display area AA. For example, the first groove 120 is tightly connected to the single-dam 110, and the single-dam 110 may serve as a groove wall, on a side away from the display area AA, of the first groove 120.

The first groove 120 is capable of accommodate the ink 200 overflowing from the display area AA, and the single-dam 110 is capable of preventing the overflowing ink 200 from crossing the single-dam 110 to prevent the ink from crossing the single-dam 110 during the IJP process, so as to improve the reliability of the display panel 100.

In some embodiments, the lines extending from the display area AA are connected to a bonding area located on a side of the display area AA. The single-dam 110 may be located in the non-display area SA on the same side as the bonding area. Hereinafter, the description will be made by taking an example in which the bonding area is located below the display area, but it should not be limited thereto. It can be understood that, as shown in FIG. 2, the single-dam 110 and the first groove 120 extend along the first direction X and surround the lower side of the display area AA.

In some other embodiments, the single-dam 110 may encircle the display area AA. For example, the single-dam 110 and the first groove 120 located on the upper or lower sides of the display area AA extend along the first direction X, and the single-dam 110 and the first groove 120 located on the left or right sides of the display area AA extend along the second direction Y.

In some examples, as shown in FIG. 2, a dimension of the single-dam 110 in the first direction X may be less than or substantially equal to a dimension of the display panel 100 in the first direction X. For example, the dimensions of the display panel 100 and the single-dam 110 in the first direction X are each in a range of 60 nm to 75 mm, such as 60 mm, 62 mm, 65 mm, 67 mm, 68.8 mm, 70 mm, 72 mm, or 75 mm.

In this case, a dimension of the first groove 120 in the first direction X may be substantially equal to the dimension of the single-dam 110 in the first direction X.

In some examples, as shown in FIG. 2, the dimension of the single-dam 110 in the second direction Y may be in a range of 35 μm to 45 μm, such as 35 μm, 37.3 μm, 38.6 μm, 39.5 μm, 40 μm, 42 μm, or 45 μm.

In some examples, a dimension of the first groove 120 in the second direction Y may be greater than the dimension of the single-dam 110 in the second direction Y, or may be less than the dimension of the single-dam 110 in the second direction Y, or may be substantially equal to the dimension of the single-dam 110 in the second direction Y, which is not limited here.

As shown in FIG. 2, in some embodiments, the display panel 100 further includes barrier structures 130. The barrier structures 130 are located between the first groove 120 and the display area. It can be understood that, in a case where the single-dam 110 and the first groove 120 are located on a side of the display area AA, the barrier structures 130 and the single-dam 110 are located on a same side of the display area AA; in a case where the single-dam 110 and the first groove 120 encircle the display area AA, the barrier structures 130 may also encircle the display area AA.

The barrier structure 130 is located between the first groove 120 and the display area AA, and the space between the first groove 120 and the display area AA may be utilized without enlarging the bezel size of the non-display area AA, compared with the solution of setting two circles of Dam in the non-display area AA, it is possible to reduce the bezel size of the non-display area AA, for example, may reduce by 60 μm to 80 μm, which facilitates the narrowing of the bezel of the display panel 100.

The barrier structure 130 includes a barrier wall 140 and a second groove 150 that is located between the barrier wall 140 and the display area AA. For example, the second groove 150 is tightly connected to the barrier wall 140, and the barrier wall 140 may serve as a groove wall, on a side away from the display area AA, of the second groove 150. The second groove 150 is capable of accommodate the ink overflowing from the display area AA, and the barrier wall 140 is capable of preventing the overflowing ink from crossing the barrier wall 140. On a basis of the single-dam 110 and the first groove 120 being able to block the ink overflow, the barrier structure 130 may further improve the ability of the display panel 100 to block ink overflow, so as to prevent the ink from crossing the single-dam 110 during the IJP process to improve the reliability of the display panel 100.

In some embodiments, as shown in FIG. 2, the barrier structure 130 is located below the display area AA, and the barrier wall 140 and the second groove 150 extend along the first direction X and encircle the lower side of the display area AA.

As shown in FIG. 2, in some examples, dimensions of the barrier wall 140 and the second groove 150 in the first direction X may each be less than or equal to the dimension of the single-dam 110 in the first direction X.

In some examples, the dimension of the barrier wall 140 in the second direction Y may be in a range of 15 μm to 25 μm, such as 15 μm, 16.5 μm, 18 μm, 20 μm, 22 μm, 23.5 μm, or 25 μm.

In some examples, the dimension of the second groove 150 in the second direction Y is greater than, or less than, or equal to the dimension of the barrier wall 140 in the second direction Y, which is not limited here.

As shown in FIG. 2, in some examples, the dimension of the barrier wall 140 in a direction perpendicular to the display panel 100 (a third direction Z) may be in a range of 1.5 μm to 2.5 μm, such as 1.5 μm, 1.8 μm, 2.0 μm, 2.2 μm, or 2.5 μm.

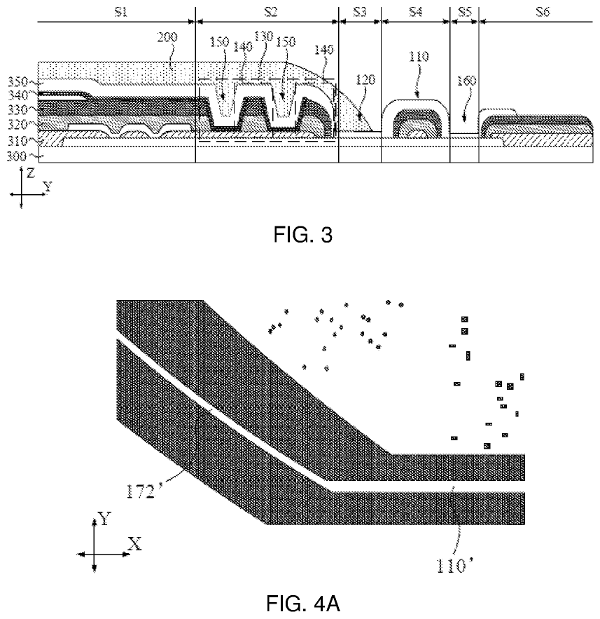

In some embodiments, as shown in FIG. 3, the display panel 100 further includes a fourth groove 160. The fourth groove 160 is located on a side of the single-dam 110 away from the display area AA. For example, the fourth groove 160 is tightly connected to the single-dam 110, and the single-dam 110 may serve as a groove wall of the fourth groove 160 at a side proximate to the display area AA.

A dimension of the fourth groove 160 in the second direction Y may be greater than, or less than, or equal to the dimension of the first groove 120 in the second direction Y, which is not limited here.

The fourth groove 160 can accommodate the ink that overflowing from the display area AA and crossing the single-dam 110, it is possible to avoid the abnormality of the display panel 100 caused by a case that the ink intrudes into outside of the single-dam 110 after crossing the single-dam 110, thereby improving the ability of the display panel 100 to block ink overflow to ensure the yield of IJP.

In a case where the display panel 100 includes the barrier structure 130, the first groove 120, the single-dam 110 and the fourth groove 160, the display panel 100 has triple protection to prevent ink overflowing from the display area AA, so as to ensure the yield of IJP. The first protection is the barrier structure 130, the second protection is the first groove 120 and the single-dam 110, and the third protection is the fourth groove 160.

In some embodiments, as shown in FIG. 3, the display panel 100 includes a substrate 300, and a first planarization pattern 310, a second planarization pattern 320, a pixel definition pattern 330, a cathode layer 340 and an inorganic encapsulation layer 350 that are sequentially formed on the substrate 300.

As shown in FIG. 3, the dimension of the barrier wall 140 in the third direction Z includes: in the third direction Z, a dimension of the first planarization pattern 310, a dimension of the second planarization pattern 320, a dimension of the pixel definition pattern 330, a dimension of the cathode layer 340, and a dimension of inorganic encapsulation layer 350.

The dimension of the second groove 150 in the third direction Z includes: the dimension of the first planarization pattern 310, the dimension of the cathode layer 340, and the dimension of the inorganic encapsulation layer 350. It can be understood that, a depth, recessed into the barrier wall 140, of the second groove 150 includes the dimension of the second planarization pattern 320 in the third direction Z and the dimension of the pixel definition pattern 330 in the third direction Z.

The dimension of the single-dam 110 in the third direction Z includes: in the third direction Z, the dimension of the first planarization pattern 310, the dimension of the second planarization pattern 320, the dimension of the pixel definition pattern 330, and the dimension of inorganic encapsulation layer 350.

The dimensions of the first groove 120 and the fourth groove 160 in the third direction Z each include the dimension of the inorganic encapsulation layer 350 in the third direction Z. It can be understood that the depths, recessed into the single-dam 110, of the first groove 120 and the fourth groove 160 each include the dimension of the first planarization pattern 310 in the third direction Z, the dimension of the second planarization pattern 320 in the third direction Z, and the dimension of the pixel definition pattern 330 in the third direction Z.

In some embodiments, as shown in FIGS. 2 and 3, the display panel 100 includes a plurality of barrier structures 130. The plurality of barrier structures 130 each extend in the first direction X and are arranged side by side in the second direction Y. For example, the plurality of second grooves 150 and the plurality of barrier walls 140 in the plurality of barrier structures 130 are alternately arranged in a direction (e.g., the second direction Y) away from the display area AA.

In some examples, the plurality of barrier structures 130 are tightly connected, and two barrier walls 140 of two adjacent barrier structures 130 respectively serve as a groove wall, at a side proximate to the display area AA, of a second groove 150 and a groove wall, at a side away from the display area AA, of the second groove 150.

In some embodiments, in the plurality of barrier structures 130, the dimensions of the plurality of barrier walls 140 in the second direction Y may be the same or different. For example, for two adjacent barrier walls 140, a dimension of one barrier wall 140 in the second direction Y is 20 μm, and a dimension of the other barrier wall 140 in the second direction Y is 22 μm.

Similarly, in the plurality of barrier structures 130, the dimensions of the plurality of second grooves 150 in the second direction Y may be the same or different. For example, for two adjacent second grooves 150, a dimension of one second groove 150 in the second direction Y is 18 μm, and a dimension of the other second groove 150 in the second direction Y is 22 μm.

As shown in FIG. 3, in a plane of the display panel 100, in a direction (e.g., the second direction Y) perpendicular to an extension direction (e.g., the first direction X) of the second groove 150, a dimension of the first groove 120 is greater than a dimension of the second groove 150.

In some embodiments, in the plurality of barrier structures 130, the dimensions of the plurality of barrier walls 140 in the third direction Z may be the same or different.

For example, for two adjacent barrier walls 140, the dimension, in the direction perpendicular to the display panel 100 (i.e., the third direction Z), of the barrier wall 140 away from the display area AA is greater than the dimension, in the direction perpendicular to the display panel 100, of the barrier wall 140 proximate to the display area AA.

In this way, the barrier structure 130 far away from the display area AA has a stronger ability, than the barrier structure 130 proximate to the display area AA, to prevent ink from overflowing, which may further improve the ability of the display panel 100 to prevent ink from overflowing, so as to prevent the ink from crossing the single-dam 110 during the IJP process to improve the reliability of the display panel 100.

The plurality of barrier structures 130 may form a continuous undulating structure between the display area AA and the first groove 120 to slow down the flow of ink overflowing from the display area AA. In addition, due to the fluctuating characteristics of the flow of ink, the flow speed of ink varies at different positions; the position where the ink first contacts the barrier wall 140 will accelerate the flow of ink at the contact point due to the increased surface tension, which causes the ink to cross the barrier wall 140 at the contact point. Based on this, as shown in FIG. 2, in some embodiments, at least one barrier wall 140 in the plurality of barrier walls 140 is provided therein with at least one notch 141.

In some examples, a barrier wall 140 may be provided therein with one or more notches 141 to form a plurality of barrier sub-walls (1401). The dimensions of the plurality of barrier sub-walls in the first direction X may or may not be equal. In addition, in a case where the display panel 100 includes a plurality of barrier walls 140, the number of notches 141 provided in different barrier walls 140 may or may not be equal. For example, a barrier wall 140 is provided therein with 2 notches 141, and another barrier wall 140 may be provided therein with no notches (that is, the number of notches 141 is zero), or may be provided therein with one notch 141 or two notches 141.

In some examples, the dimension of the notch 141 in the first direction X may be in a range of 200 μm to 500 μm, such as 200 μm, 250 μm, 300 μm, 350 μm, 400 μm, 450 μm or 500 μm.

Considering an example in which a barrier wall 140 includes two notches 141 and three barrier sub-walls and the dimensions of the three barrier sub-walls in the first direction X are equal, the dimension of the barrier wall 140 in the first direction X is L1, and the dimension of the notch 141 in the first direction X is L2, and then the dimension of each barrier sub-wall in the first direction X is L3=(L1−2L2)/3.

In some embodiments, the display panel 100 includes two barrier structures 130, the notch 141 provided in the barrier wall in the barrier structure 130 on the side proximate to the display area AA is communicated with both the second groove 150 in the barrier structure 130 on the side proximate to the display area AA and the second groove 150 in the barrier structure 130 on the side away from the display area AA.

In some embodiments, the display panel 100 includes a barrier structure 130; the notch 141 provided in the barrier wall 140 of the barrier structure 130 is communicated with both the second groove 150 of the barrier structure 130 and the first groove 120.

By providing the notch 141 in the barrier wall 140, the ink overflowing from the display area AA may be released through the notch 141 after being blocked by the barrier wall 140 and enter the first groove 120 or the second groove 150 that is in the barrier structure 130 on the outside, so as to slow down or stop the flow of ink. Thus, it is possible to improve the ability of the display panel 100 to prevent ink from overflowing, so as to prevent the ink from crossing the single-dam 110 during the IJP process to improve the reliability of the display panel 100.

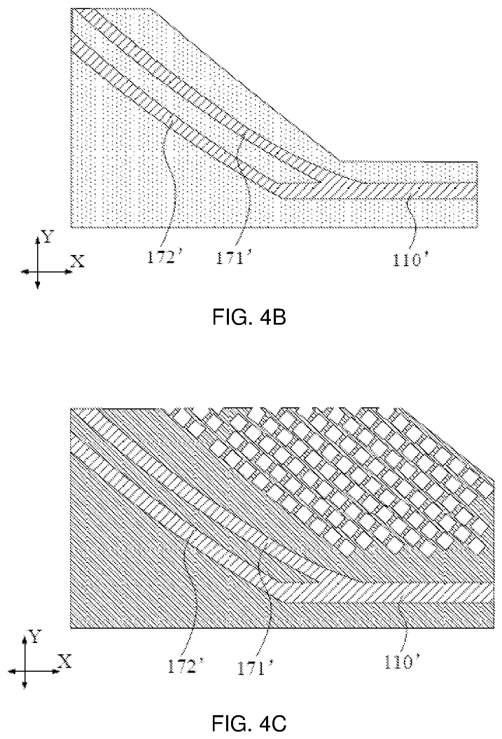

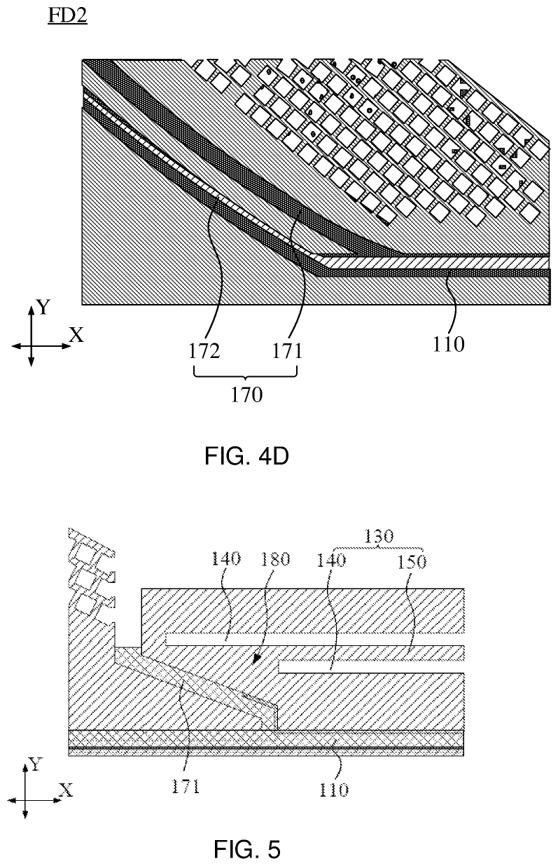

In some embodiments, as shown in FIG. 4D, the display panel 100 further includes a double-dam 170. The double-dam 170 is located on at least one side of the display area AA, and the single-dam 110 and the double-dam 170 are located on different sides of the display area AA. For example, as shown in FIGS. 1 and 4D, the single-dam 110 is located on the lower side of the display area AA, and the double-dam 170 is located on the left side of the display area AA.

The double-dam 170 includes a first dam body 171 and a second dam body 172 spaced apart from each other. The first dam body 171 is located between the second dam body 172 and the display area AA. It can be understood that the first dam body 171 is disposed proximate to the display area AA, and the second dam body 172 is disposed away from the display area AA.

A dimension of the first dam body 171 in a direction perpendicular to an extension direction of itself may be equal to or less than or greater than a dimension of the second dam body 172 in a direction perpendicular to an extension direction of itself. For example, the dimension of the first dam body 171 in the direction perpendicular to the extension direction of itself is 30 μm, and the dimension of the second dam body 172 in the direction perpendicular to the extension direction of itself is 30 μm.

In addition, as shown in FIG. 4D, the dimension of the first dam body 171 in the direction perpendicular to the extension direction of itself and the dimension of the second dam body 172 in the direction perpendicular to the extension direction of itself may be less than a dimension of the single-dam 110 in a direction perpendicular to an extension direction of itself, for example, in the second direction Y. For example, the dimension of the first dam body 171 in the direction perpendicular to the extension direction of itself is 30 μm, the dimension of the second dam body 172 in the direction perpendicular to the extension direction of itself is 30 μm, and the dimension of the single-dam 110 in the direction perpendicular to the extension direction of itself is 40 μm.

In some examples, the dimension of the second dam body 172 in the third direction Z is greater than the dimension of the first dam body 171 in the third direction Z. In this way, the second dam body 172 has a stronger ability, than the first dam 171, to prevent ink from overflowing, which may further improve the ability of the display panel 100 to prevent ink from overflowing to ensure the yield of IJP.

For example, when the first planarization pattern 310 in the display panel 100 is formed, as shown in FIG. 4A, a first planarization material is retained at a position 172′ corresponding to the second dam body 172 and a position 110′ corresponding to the single-dam 110; when the second planarization pattern 320 in the display panel 100 is formed, as shown in FIG. 4B, a second planarization material is retained at the position 171′ corresponding to the first dam body 171, the position 172′ corresponding to the second dam body 172 and the position 110′ corresponding to the single-dam 110; when the pixel definition pattern 330 in the display panel 100 is formed, as shown in FIG. 4C, a pixel definition material is retained at the position 171′ corresponding to the first dam body 171, the position 172′ corresponding to the second dam body 172 and the position 110′ corresponding to the single-dam 110.

Therefore, after the pixel definition pattern 330 is formed, as shown in FIG. 4D, the first dam body 171 including the second planarization material and the pixel defining material is formed at the position 171′ corresponding to the first dam body 171, the second dam body 172 including the first planarization material, the second planarization material and the pixel defining material is formed at the position 172′ corresponding to the second dam body 172, and the single-dam 110 including the first planarization material, the second planarization material and the pixel defining material is formed at the position 110′ corresponding to the single-dam 110.

In this way, it is possible to achieve that the dimension of the second dam body 172 in the third direction Z is greater than the dimension of the first dam body 171 in the third direction Z.

In some embodiments, as shown in FIG. 1 and FIGS. 4A to 4D, a connection region between the single-dam 110 and the double-dam 170 may be located in a corner region of the display panel 100, for example, the lower left corner region where the left side of the display area AA meets the lower side of the display area AA, or the upper right corner where the right side of the display area AA meets the upper side of the display area AA.

In some examples, as shown in FIGS. 4A to 4D, in the connection region between the single-dam 110 and the double-dam 170, the single-dam 110 is connected to both the first dam body 171 and the second dam body 172 to form a one-piece structure. In some other examples, in the connection region of the single-dam 110 and the double-dam 170, the first dam body 171 and the second dam body 172 may be connected to each other, and then connected to the single-dam 110 to form a one-piece structure.

In this way, the double-dam 170 and the single-dam 110 may jointly encircle the display area AA, thereby ensuring completely preventing ink overflowing from the display area AA to improve the reliability of the display panel 100.

In some embodiments, as shown in FIG. 5, an edge of the barrier structure 130 is spaced apart from the double-dam 170. For example, an end of the barrier wall 140 of the barrier structure 130 proximate to the double-dam 170 is spaced apart from the first dam body 171, so that an opening 180 is formed between the barrier wall 140 and the first dam body 171.

Since there is no notch 141 in the first dam body 171, the ink overflowing from the display area AA may flow along the first dam body 171 through the opening 180, which has the function of guiding the ink to flow from the opening 180.

In some examples, a dimension of the opening 180 in the first direction X may be greater than, or less than or equal to the dimension of the notch 141 in the first direction X.

By providing the opening 180, the ink overflowing from the display area AA may be released through the notch 141 after being blocked by the barrier wall 140 and the first dam body 171, and enter the first groove 120 or the second groove 150 that is in the next barrier structure 130, so as to slow down or stop the flow of ink. Thus, it is possible to improve the ability of the display panel 100, and ensure that the ink does not damage the structure on the outer side of the single-dam 110 during the IJP process to improve the reliability of the display panel 100.

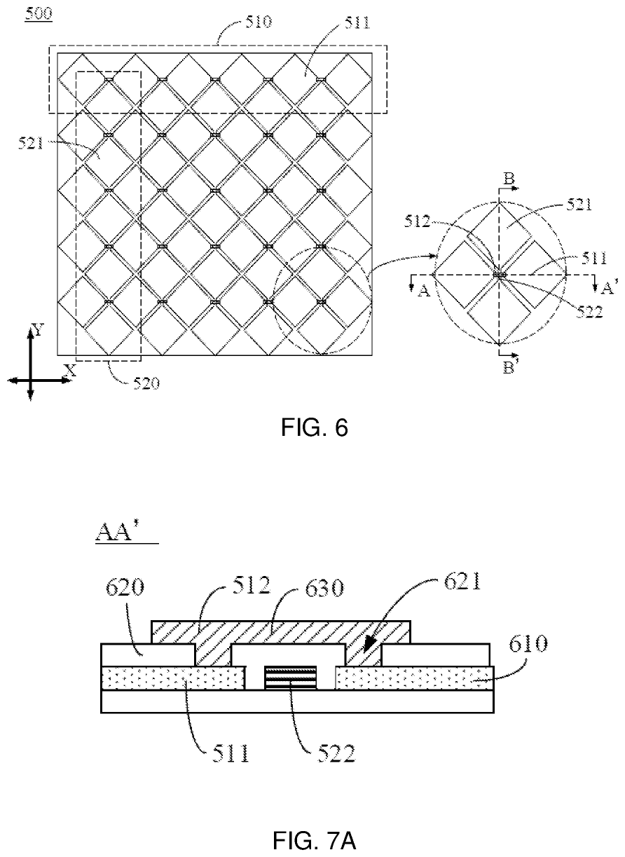

In some embodiments, as shown in FIG. 6, the display panel 100 includes a touch structure 500. For example, the touch structure 500 may be a flexible multi-layer on cell (FMLOC) touch structure.

As shown in FIG. 6, in the display area AA, the touch structure 500 may include a plurality of driving units 510 and a plurality of sensing units 520 that are insulated from each other. Each driving unit 510 includes a plurality of driving electrodes 511 arranged side by side in the first direction X, and first connection portions 512 each electrically connects two adjacent driving electrodes 511. Each sensing unit 520 includes a plurality of sensing electrodes 521 arranged side by side in the second direction Y, and second connection portions 522 each electrically connects two adjacent sensing electrodes 521.

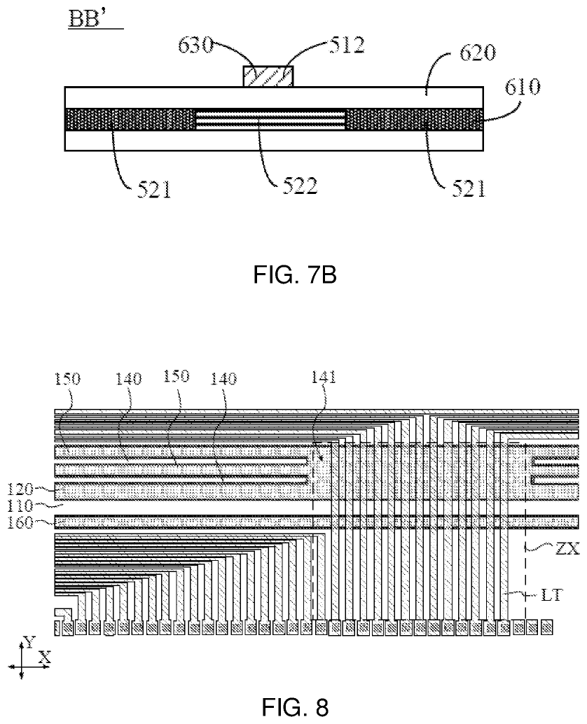

As shown in FIGS. 7A and 7B, the touch structure includes a first metal layer 610, an insulating layer 620 and a second metal layer 630 that are stacked in sequence, and the insulating layer 620 is provided therein with a plurality of via holes 621.

For example, the driving electrodes 511, the first connection portions 512 and the sensing electrodes 521 of the touch structure are located in one of the first metal layer 610 and the second metal layer 630, the second connection portions 522 are located in the other of the first metal layer 610 and the second metal layer 630, and the second connection portion 522 is electrically connected to two adjacent sensing electrodes 521 through the via holes 621.

For example, the driving electrodes 511, the second connection portions 522 and the sensing electrodes 521 are located in one of the first metal layer 610 and the second metal layer 630, the first connection portions 512 are located in the other of the first metal layer 610 and the second metal layer 630, and the first connection portion 512 is electrically connected to two adjacent driving electrodes 511 through the via holes 621.

For example, the driving electrodes 511, the sensing electrodes 521, the first connection portions 512 and the second connection portions 522 in the display area AA may be of a metal mesh structure.

On this basis, as shown in FIGS. 8 to 13, the display panel 100 further includes a wiring area ZX. The wiring area ZX and the single-dam 110 are located on the same side of the display area AA. The wiring area ZX includes touch lines LT extending outward from the display area AA, and the touch line LT includes a first line and a second line. The first line may be coupled to the first metal layer 610, and the second line may be coupled to the second metal layer 630; alternatively, the first line may be coupled to the second metal layer 630, and the second line may be coupled to the first metal layer 610.

In some examples, a dimension of the wiring area in the first direction X is approximately equal to 400 μm.

In some embodiments, a flatness of a portion of the at least one barrier structure 130 in the wiring area ZX is greater than a flatness of a portion of the at least one barrier structure 130 outside the wiring area ZX. It will be understood that, for all the barrier structures 130 between the first groove 120 and the display area AA, the flatness in the wiring area is greater than the flatness outside the wiring area.

The flatness in the wiring area is greater than the flatness outside the wiring area, which may be understood as the total number of grooves and barrier walls 140 in the wiring area is less than the total number of grooves and barrier walls 140 outside the wiring area. For example, in a case where a second groove 150 in the wiring area is filled, two barrier walls 140 adjacent to the original second groove 150 in the wiring area and a part filled the second groove 150 serve as one barrier wall 140 together, so that there is one less protrusion and one less depression in the wiring area than the outside of the wiring area.

The flatness of the portion of at least one barrier structure 130 in the wiring area ZX is set to be greater than the flatness of the portion of the at least one barrier structure 130 outside the wiring area ZX. Thus, it is possible to ensure the ability to prevent the ink from overflowing from the display area AA at the outside of the wiring area, and moreover, it is possible to improve the flatness in the wiring area to avoid the problem of metal remain due to the production of touch lines, so as to improve the yield of the touch structure.

In some examples, as shown in FIG. 8, in one or more barrier structures 130 between the first groove 120 and the display area AA, barrier wall(s) 140 in at least one barrier structure 130 are provided therein with at least one notch 141, and the wiring area is located in notch(es) 141 of at least one barrier wall 140.

The wiring area is located in the notches 141 of the at least one barrier wall 140, which may be understood that the dimension of the notch 141 of the barrier wall 140 in the first direction X is greater than or equal to the dimension of the wiring area in the first direction X. For example, two edges of the notch 141 respectively coincide with two borders of the wiring area in the first direction X. For another example, the two edges of the notch 141 are respectively located outside the two borders of the wiring area in the first direction X.

It will be noted that in a case where a same barrier wall 140 is provided therein with a plurality of notches 141, the dimension, in the first direction X, of the notch 141 located outside the wiring area may be greater than less than or equal to the dimension, in the first direction X, of the notch 141 corresponding to the wiring area.

The wiring area is located in the notch 141 of one barrier wall 140, which is equivalent to a case that two grooves on two sides of the original barrier wall 140 in the wiring area are communicated with each other and combine into one groove. Between the first groove 120 and the display area AA, there is one less protrusion and one less depression in the wiring area than outside of the wiring area.

In a case where the barrier walls 140 in the plurality of barrier structures 130 are provided therein with notches 141, and the wiring area is located in the notches 141 of the plurality of barrier walls 140, as for the effect of each barrier wall 140 is provide therein with notch 141, reference will be made to the above situation that the wiring area is located in the notch 141 of one barrier wall 140, which will not be repeated here.

As shown in FIG. 8, in some examples, in one or more barrier structures 130 between the first groove 120 and the display area AA, each barrier wall 140 is provided therein with a notch, and the wiring area is located in all the notches 141 provided in all the barrier walls 140 to communicate the first groove 120 and all the second grooves 150; the touch lines pass through the notches 141 provided in all the barrier walls 140.

The wiring area is located in all the notches 141 provided in all the barrier walls 140, which will be understood that, there is no barrier wall 140 in the wiring area, and the plurality of second grooves 150 in the wiring area are all merged into one groove, which greatly improves the flatness in the wiring area to avoid the problem of metal remain due to the production of touch lines, so as to improve the yield of the touch structure.

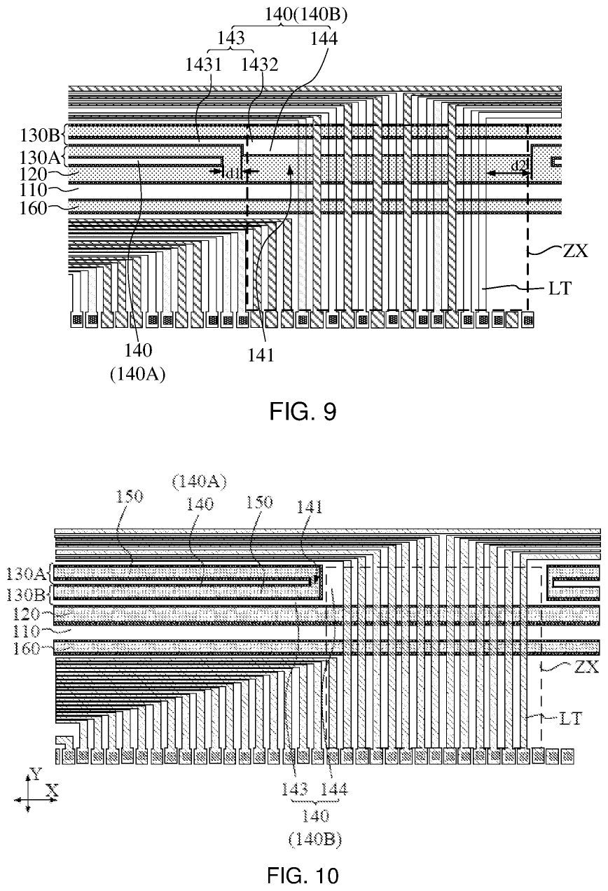

As shown in FIG. 9, in some embodiments, two adjacent barrier structures 130 include a first barrier structure 130A and a second barrier structure 130B. The barrier wall 140A of the first barrier structure 130A is provided with a notch 141 in the wiring area, and the barrier wall 140B of the second barrier structure 130B is provided with no notch 141 in the wiring area.

In some examples, the barrier wall 140B provided with no notch 141 in the wiring area includes a wall body 143 and an extension wall 144. The wall body 143 is disposed between the first groove 120 and the display area AA, and is arranged around at least part of the display area AA. As shown in FIG. 9, the wall body 143 includes a first portion 1431 located outside the wiring area and a second portion 1432 located in the wiring area, and the first portion 1431 and the second portion 1432 are connected to each other to be a one-piece structure. The extension wall 144 is located in the wiring area and connected to the second portion 1432. For example, the extension wall 144 and the second portion 1432 are connected to each other to be a one-piece structure, so that the extension wall 144 and the wall body 143 are connected to each other to be a one-piece structure.

As shown in FIG. 9, in some examples, the extension wall 144 does not extend into the notch 141 provided in the adjacent barrier wall 140A. It will be understood that the extension wall 144 is only located in the second groove 150 in the barrier structure 130B to which it belongs. For example, in the wiring area, the extension wall 144 covers the entire second grooves 150 in the barrier structure 130B to which it belongs. For another example, in the wiring area, the extension wall 144 covers part of the second groove 150 in the barrier structure 130 to which it belongs.

In some examples, in a direction (the second direction Y) perpendicular to the extension direction of the barrier wall 140, a sum of a dimension of the extension wall and a dimension of the wall body is substantially equal to the dimension of the single-dam 110. For example, the dimension of the extension wall in the second direction Y is 20 μm, the dimension of the wall body in the second direction Y is 20 μm, and the dimension of the single-dam 110 in the second direction Y is 40 μm.

In this way, it is equivalent to forming a structure of two layers of single-dams 110 in the wiring area, while there is still a structure of one layer of single-dam 110 outside the wiring area, and overall the bezel size is only one layer of single-dam 110, which facilitates the narrowing the bezel of the display panel 100.

As shown in FIG. 10, in some examples, the extension wall 144 extends into the notch 141 provided in the adjacent barrier wall 140A. It will be understood that the extension wall 144 passes through the second groove 150 in the barrier structure (i.e., the second barrier structure 130B) to which it belongs, and extends into the notch 141 provided in the barrier wall 140A in the adjacent barrier structure (i.e., the first barrier structure 130A).

In addition, on this basis, the extension wall 144 may also extend into the notch 141 disposed in the barrier wall 140 in the first barrier structure 130A and extend into the second groove 150 in the first barrier structure 130A. In some examples, as shown in FIG. 10, the extension wall 144 extends into all the second grooves 150 between the first groove 120 and the display area AA.

As shown in FIGS. 9 and 10, in some examples, the dimension of the extension wall 144 in the first direction X may be less than the dimension of the notch 141 in the first direction X.

As shown in FIG. 9, for example, the extension wall 144 is located in the middle of the notch 141. In the first direction X, a distance d1 between the extension wall 144 and an edge of the notch 141 may be in a range of 20 μm to 70 μm, such as 20 μm, 25 μm, 30 μm, 36 μm, 42 μm, 50 μm, 57 μm, 66 μm, or 70 μm.

In this way, no matter whether the extension wall 144 extends into the notch 141 provided in the barrier wall 140A, there is a gap between the extension wall 144 and the edge of the notch 141, and the gap may be communicated with the two second grooves 150 in two adjacent barrier structures 130.

As shown in FIG. 9, in some embodiments, a distance d2 between an outermost line among the plurality of touch lines in the wiring area and an outer wall of the extension wall 144 may be in a range of 15 μm to 120 μm, such as 15 μm, 20 μm, 30 μm, 40 μm, 50 μm, 60 μm, 70 μm, 80 μm, 90 μm, 100 μm, 110 μm or 120 μm.

In this way, there may be a certain degree of position error in the production position of the touch lines on the extension wall 144. Within the allowed position error, the touch lines are all located on the extension wall 144, so that the flatness in the wiring area may be improved due to the extension wall, so as to improve the manufacturing yield of touch lines.

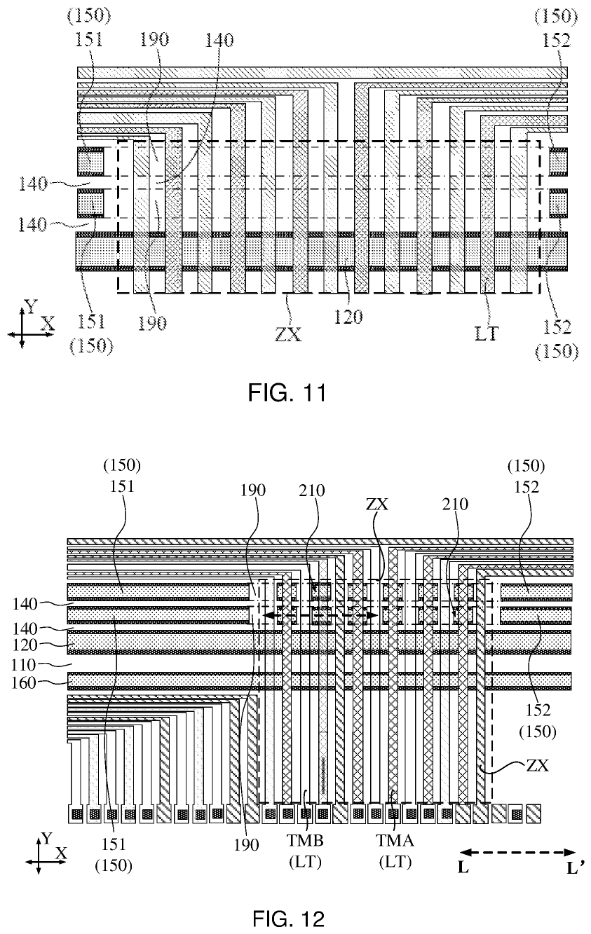

As shown in FIG. 11, in some embodiments, the barrier structure 130 further includes a barrier platform 190. The barrier platform 190 is disposed in the wiring area and is disposed in a second groove 150. The barrier platform 190 divides the second groove 150, in the first direction X, into a first groove section 151 and a second groove section 152 that are independent of each other. It will be understood that the barrier platform 190 is blocked between the first groove section 151 and the second groove section 152 in the wiring area ZX, so that the first groove section 151 and the second groove section 152 are independent of each other.

In some examples, a surface of the barrier platform 190 away from the substrate 300 and a surface of the barrier wall 140 away from the substrate 300 constitute a substantially flat surface. The position of the barrier platform 190 in the wiring area is adjacent to the position of the barrier wall 140 in the wiring area, and the barrier platform 190 may be connected to two barrier walls 140 adjacent thereto on both sides to form a one-piece structure. In this way, there may be less at least one second groove 150 in the wiring area, and the barrier platform(s) 190 and the barrier walls 140 are combined into one platform to carry the touch lines, thereby improving the flatness in the wiring area between the first groove 120 and the display area AA to improve the manufacturing yield of touch lines.

In some examples, as shown in FIG. 11, each second groove 150 includes a barrier platform 190. In the wiring area, a plurality of barrier platforms 190 and a plurality of barrier walls 140 together constitute a platform for carrying the touch lines. It will be understood that the platform covers all the second grooves 150 in the wiring area, so that at least one barrier structure 130 in the wiring area actually has a flat surface, i.e., a surface of the platform away from the substrate 300.

It will be noted that in a case where the barrier structure 130 includes the barrier platform(s) 190, no notch is provided in the barrier wall 140, or the notch 141 is provided outside the wiring area ZX, which is not limited here.

As shown in FIG. 12, in the extension direction of the barrier wall 140, e.g., the first direction X, the barrier platform 190 is provided therein with a plurality of third grooves 210 spaced apart from each other.

In some examples, the number of third grooves 210 is equal to the number of first lines TMA in the touch lines. An orthographic projection of the first line TMA on the substrate 300 overlaps with an orthographic projection of the third groove 210 on the substrate 300. An orthographic projection of the second line TMB on the substrate 300 is located between orthographic projections of two third grooves 210, adjacent to each other in the extension direction of the barrier wall 140 (e.g., the first direction X), on the substrate 300.

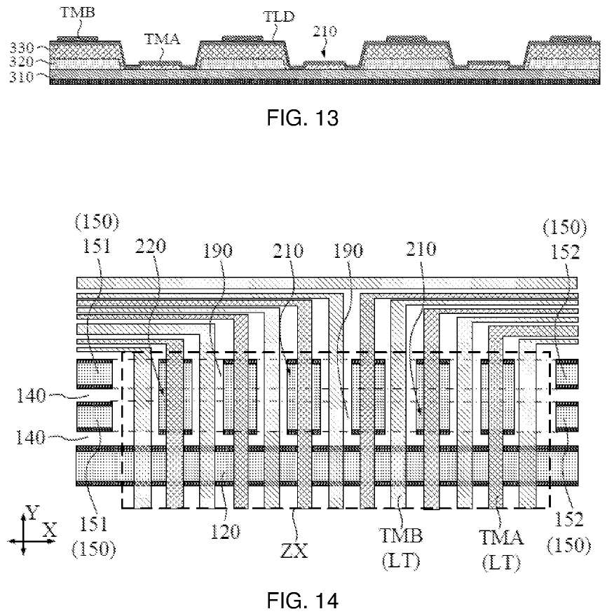

It will be understood that, as shown in FIG. 13, the second lines TMB are each located on the flat platform, and the first lines TMA are each located on the third groove 210 and the barrier wall 140. In this way, it is possible to avoid the risk of short circuit between the first line TMA and the second line TMB, and moreover, it is possible to improve the manufacturing yield of the second lines TMB; the manufacturing yield of the first lines TMA remains unchanged, so that the overall manufacturing yield of the touch lines may be improved.

In some examples, the number of third grooves 210 is equal to the number of second lines TMB. An orthographic projection of the second line TMB on the substrate 300 overlaps with an orthographic projection of the third groove 210 on the substrate 300. An orthographic projection of the first line TMA on the substrate 300 is located between orthographic projections of two third grooves 210, adjacent to each other in the extension direction of the barrier wall 140 (e.g., the first direction X), on the substrate 300.

It will be understood that the first lines TMA are each located on the flat platform, and the second lines TMB are each located on the third groove 210 and the barrier wall 140. In this way, the manufacturing yield of the first lines TMA is improved, the manufacturing yield of the second lines TMB remains unchanged, so that the overall manufacturing yield of the touch lines may be improved.

In some examples, a dimension of the third groove 210 in the first direction X is in a range of 25 μm to 35 μm, inclusive; a dimension of the third groove 210 in the second direction Y is in a range of 23 μm to 30 μm, inclusive. For example, the dimension of the third groove 210 in the first direction X is 30 μm, and the dimension of the third groove 210 in the second direction Y is 28 μm.

As shown in FIG. 14, in some embodiments, in a direction (e.g., the second direction Y) perpendicular to the barrier wall 140, the barrier wall 140 between two adjacent barrier platforms 190 is provided therein with a through hole 220, and the through hole 220 is communicated with two third grooves 210 that are adjacent to each other in the direction perpendicular to the barrier wall 140.

A dimension of the through hole 220 in the first direction X may be substantially equal to a dimension of the third groove 210 in the first direction X. A dimension of the through hole 220 in the second direction Y may be substantially equal to a dimension of the barrier wall 140 in the second direction Y. In this way, two third grooves 210 that are adjacent to each other in the second direction Y and the through hole 220 between the two third grooves 210 may be combined into one groove.

In a case where the orthographic projection of the first line TMA on the substrate 300 overlaps with the third groove 210, two adjacent third grooves 210 and the through hole 220 between the two third grooves 210 are combined into one groove, which may improve the flatness between the first line TMA and the substrate 300, thereby improving the manufacturing yield of the first line TMA.

In a case where the orthographic projection of the second line TMB on the substrate 300 overlaps with the third groove 210, two adjacent third grooves 210 and the through hole 220 between the two third grooves 210 are combined into one groove, which may improve the flatness between the second line TMB and the substrate 300, thereby improving the manufacturing yield of the second line TMB.

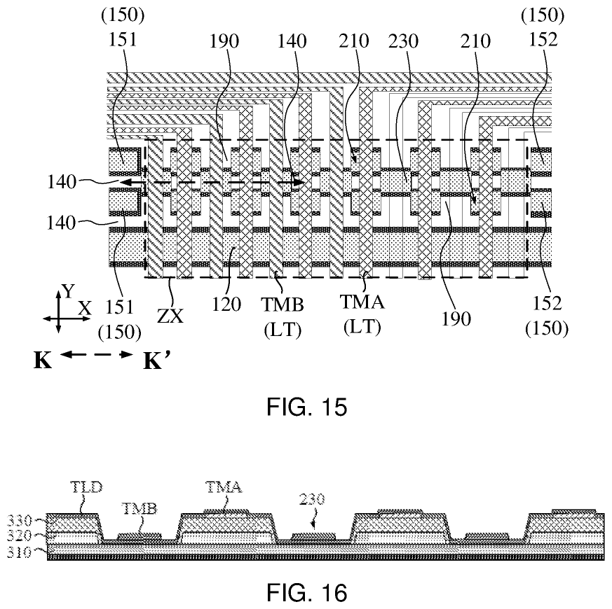

As shown in FIG. 15, in some embodiments, the barrier wall 140 is provided therein with a fifth groove 230. The fifth groove 230 and the third groove 210 are arranged, in the first direction X, in a staggered manner.

In some examples, the fifth groove 230 may be or may not be communicated with the third groove 210 on the periphery, which is not limited here.

As shown in FIG. 16, in some examples, the number of fifth grooves 230 is equal to the number of second lines TMB in the touch lines. An orthographic projection of the second line TMB on the substrate 300 overlaps with an orthographic projection of the fifth groove 230 on the substrate 300. An orthographic projection of the first line TMA on the substrate 300 overlaps with an orthographic projection of the third groove 210 on the substrate 300.

It will be understood that, as shown in FIG. 16, the first line TMA is located on the barrier wall 140 between the two third grooves 210 in the second direction Y, and the second line TMB is located on the fifth groove 230 and the barrier platforms 190.

In some examples, the number of fifth grooves 230 is equal to the number of first lines TMA. An orthographic projection of the first line TMA on the substrate 300 overlaps with an orthographic projection of the fifth groove 230 on the substrate 300. An orthographic projection of the second line TMB on the substrate 300 overlaps with an orthographic projection of the third groove 210 on the substrate 300.

As shown in FIGS. 11 to 16, in some embodiments, the first lines TMA and the second lines TMB each extend in the second direction Y, and are arranged side by side in the first direction X. For example, in the first direction X, the first lines TMA and the second lines TMB are alternately arranged.

On the basis of ensuring that the flatness of the portion of the plurality of barrier structures 130 in the wiring area is greater than the flatness of the portion of the plurality of barrier structures 130 outside of the wiring area, by proving the fifth grooves 230 in the barrier wall 140, it is possible to further increase the number of grooves in the wiring area that accommodate the ink overflowing from the display area AA to improve the ability of the barrier structure 130 to block the ink, so that the reliability of the display panel 100 is improved.

It will be noted that, as shown in FIGS. 13 and 16, the display panel 100 further includes a touch insulating layer TLD. The touch insulating layer TLD is configured to isolate the electrical connection between the first line TMA and the second line TMB to avoid the short circuit between the first line TMA and the second line TMB, so as to improve the reliability of the touch structure 500.

In summary, in the display panel 100 provided by the embodiments of the present disclosure, at least one barrier structure 130 is disposed between the first groove 120 and the display area AA, which may improve the ability of the display panel 100 to block ink overflowing from the display area AA on the basis of shortening the bezel size of the display panel 100, so as to improve the production yield of IJP. In addition, the wiring area is designed variously, so it is possible to improve the flatness in the wiring area on the basis of ensuring the ink blocking ability outside of the wiring area, so as to improve the manufacturing yield of the touch lines.

Embodiments of the present disclosure provide a manufacturing method of a display substrate. As shown in FIG. 3, the manufacturing method includes the following steps.

In a first step, a substrate 300 is provided.

As shown in FIG. 3, in a direction away from the display area AA (e.g., the second direction Y), the substrate 300 may include a first region S1, a second region S2, a third region S3, a fourth region S4, a fifth region S5 and a sixth region S6. The first region S1 may include a display area AA.

In a second step, a first planarization pattern 310 is formed on the substrate 300.

The first planarization pattern 310 includes a first planarization portion, a second planarization portion, and a third planarization portion that are spaced apart in the second direction Y. The first planarization portion may be continuously disposed in the first region and the second region, the second planarization portion is located in the fourth region, and the third planarization portion is located in the sixth region.

In this way, since there is no first planarization pattern 310 in the third region and the fifth region, the third region forms a first depression relative to the adjacent second region and the fourth region, and the fifth region forms a second depression relative to the fourth region and the sixth region.

In a third step, a second planarization pattern 320 is formed on the first planarization pattern 310.

The second planarization pattern 320 includes a fourth planarization portion, a fifth planarization portion, a sixth planarization portion and a seventh planarization portion that are spaced apart in the second direction Y.

The fourth planarization portion may be located on a side of the first planarization portion away from the substrate 300 and located in the first region.

The fifth planarization portion may be located on a side of the first planarization portion away from the substrate 300 and located in the second region. There may be a plurality of fifth planarization portions. In a case where there are a plurality of fifth planarization portions, the plurality of fifth planarization portions may be arranged at intervals in a direction away from the display area AA.

The sixth planarization portion may be located in the fourth region and cover the second planarization portion.

The seventh planarization portion may be located in the sixth region and cover the third planarization portion.

The fifth planarization portion is provided therein with a third depression. In addition, in a case where the number of fifth planarization portions is greater than or equal to 2, another third depression is provided between two adjacent fifth planarization portions. It will be understood that, an orthographic projection of edges of the third depression on the substrate 300 are located within an orthographic projection of the first planarization portion on the substrate 300.

In addition, since there is no second planarization pattern 320 in the third region and the fifth region, dimensions of the first depression and the second depression in the third direction Z are each further increased.

In a fourth step, a pixel definition pattern 330 is formed on the second planarization pattern 320.

The pixel definition pattern 330 includes a first pixel definition portion, a second pixel definition portion, a third pixel definition portion, and a fourth pixel definition portion that are spaced apart in the second direction Y.

The first pixel definition portion may be located on a side of the fourth planarization portion away from the substrate 300 and located in the first region.

The second pixel definition portion may be located in the second region, cover the fifth planarization portion, and not located in the third recess.

The third pixel definition portion may be located in the fourth region and cover the sixth planarization portion.

The fourth pixel definition portion may be located in the sixth region and cover the seventh planarization portion.

The first pixel definition portion covers the fourth planarization portion, and the second pixel definition portion covers the fifth planarization portion and is not located in the third recess, so that the dimension of the third recess in the third direction Z is further increased.

In addition, since there is no pixel definition pattern 330 in the third region and the fifth region, the dimensions of the first recess and the second recess in the third direction Z are each further increased.

In a fifth step, a cathode layer 340 is formed on a side of the pixel definition pattern 330 away from the substrate 300.

The cathode layer 340 is located in the first region and the second region. For example, an orthographic projection of the cathode layer 340 on the substrate 300 overlaps with an orthographic projection of the first planarization portion on the substrate 300, and is non-overlapping with both an orthographic projection of the second planarization portion on the substrate 300 and an orthographic projection of the third planarization portion on the substrate 300. The cathode layer 340 may cover the third recess.

In a sixth step, an inorganic encapsulation layer 350 is formed on a side of the cathode layer 340 away from the substrate 300.

The inorganic encapsulation layer 350 may be an inorganic layer proximate to the substrate 300 in the encapsulation layer. The inorganic encapsulation layer 350 covers the first region, the second region, the third region, the fourth region, the fifth region and at least part of the sixth region. In this case, in the third region and the fifth region, there are no first planarization pattern 310, second planarization pattern 320, pixel definition pattern 330 and cathode layer 340 between the inorganic encapsulation layer 350 and the substrate 300.

By means of the above manufacturing method of the display panel 100, a barrier structure 130 may be formed in the second region. For example, the fifth planarization portion, the second pixel definition portion, the cathode layer 340 and the inorganic encapsulation layer 350 in the second region together constitute a barrier wall 140 of the barrier structure 130. In the second region, the third recess provided in the fifth planarization portion or the third recess between two adjacent fifth planarization portions, the cathode layer 340 and the inorganic encapsulation layer 350 together constitute a second groove 150 of the barrier structure 130.

By means of the above manufacturing method of the display panel 100, a single-dam 110 may be formed in the fourth region. For example, in the fourth region, the second planarization portion, the sixth planarization portion, the third pixel definition portion and the inorganic encapsulation layer 350 together constitute the single-dam 110.

In the third region, the first recess and the inorganic encapsulation layer 350 together constitute a first groove 120. In the fifth region, the second recess and the inorganic encapsulation layer 350 together constitute the fourth groove 160.

In summary, by means of the manufacturing method of the display panel 100 provided by the embodiments of the present disclosure, it is possible to form the single-dam 110 and the first groove 120 on at least one side of the display area AA and the barrier structure 130 between the first groove 120 and the display area AA. Thus, it is possible to improve the ability of the display panel 100 to block the ink overflowing from the display area AA on the basis of reducing the bezel size of the display panel 100, thereby improving the manufacturing yield of the display panel 100.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a single-dam located on at least one side of a display area of the display panel and disposed around at least part of the display area, the single-dam and the display area being provided therebetween with a first groove; and
at least one barrier structure located between the first groove and the display area and arranged around the at least part of the display area; wherein each barrier structure includes a barrier wall and a second groove that is located between the barrier wall and the display area.

2. The display panel according to claim 1, wherein the at least one barrier structure includes a plurality of barrier structures; wherein
a plurality of second grooves and a plurality of barrier walls in the plurality of barrier structures are alternately arranged in a direction away from the display area.

3. The display panel according to claim 2, wherein at least one barrier wall of the plurality of barrier walls is provided therein with at least one notch; wherein
a notch is communicated with two second grooves that are located on two sides of the notch, or communicated with the first groove and a second groove that are located on two sides of the notch.

4. The display panel according to claim 1, further comprising a wiring area located on a same side of the display area as the single-dam, the wiring area being provided therein with touch lines extending outward from the display area; wherein
a flatness of a portion of the at least one barrier structure in the wiring area is greater than a flatness of a portion of the at least one barrier structure outside the wiring area.

5. The display panel according to claim 4, wherein at least one barrier wall of the at least one barrier structure is are provided therein with at least one notch;
the wiring area is located in a notch of the at least one barrier wall.

6. The display panel according to claim 5, wherein the at least one barrier structure includes a plurality of barrier structures, all barrier walls in the plurality of barrier structures are each provided therein with a notch to communicate the first groove and all second grooves in the plurality of barrier structures, and the wiring area is located in notches provided in all the barrier walls.

7. The display panel according to claim 5, wherein the at least one barrier structure includes a plurality of barrier structures, two adjacent barrier structures in the plurality of barrier structures include a first barrier structure and a second barrier structure; a barrier wall of the first barrier structure is provided with a notch in the wiring area, and a barrier wall of the second barrier structure is provided with no notch in the wiring area;
the barrier wall in the second barrier structure includes:
a wall body arranged around the at least part of the display area; and
an extension wall located in the wiring area and on a side of the wall body proximate to the barrier wall of the first barrier structure; wherein the extension wall and the wall body are connected to each other to be a one-piece structure.

8. The display panel according to claim 7, wherein in a direction perpendicular to an extension direction of the barrier wall, a sum of a dimension of the extension wall and a dimension of the wall body is substantially equal to a dimension of the single-dam.

9. The display panel according to claim 7, wherein the extension wall passes through the notch disposed in the barrier wall in the first barrier structure and extends into a second groove in the first barrier structure.

10. The display panel according to claim 4, the barrier structure further includes:
a barrier platform located in the wiring area, wherein a surface of the barrier platform away from a substrate of the display panel and a surface of the barrier wall away from the substrate constitute a substantially flat surface; the barrier platform is disposed in the second groove and divides the second groove into a first groove section and a second groove section; wherein
a barrier platform of a barrier structure in the at least one barrier structure is connected to a barrier wall located on at least one side of the barrier platform to form a one-piece structure.

11. The display panel according to claim 10, wherein the at least one barrier structure includes a plurality of barrier structures, each second groove is provided therein with a barrier platform; wherein
in the wiring area, a plurality of barrier platforms and a plurality of barrier walls in the plurality of barrier structures together constitute a platform for carrying the touch lines.

12. The display panel according to claim 11, wherein in an extension direction of the barrier wall, a barrier platform of the plurality of barrier platforms is provided therein with a plurality of third grooves spaced apart from each other;
the touch lines include a plurality of first lines and a plurality of second lines; wherein
an orthographic projection of a first line on the substrate overlaps with an orthographic projection of a third groove on the substrate; an orthographic projection of a second line on the substrate is located between orthographic projections of two third grooves, adjacent to each other in the extension direction of the barrier wall, on the substrate.

13. The display panel according to claim 12, wherein in a direction perpendicular to the barrier wall, a barrier wall between two adjacent barrier platforms is provided therein with a through hole, and the through hole is communicated with two third grooves that are adjacent to each other in the direction perpendicular to the barrier wall
the orthographic projection of the first line on the substrate further overlaps with an orthographic projection of the through hole on the substrate.

14. The display panel according to claim 3, wherein a dimension of the notch in an extending direction of the second groove is in a range of 200 μm to 500 μm, inclusive.

15. The display panel according to claim 2, wherein for two adjacent barrier walls, a dimension, in a direction perpendicular to the display panel, of a barrier wall away from the display area is greater than the dimension, in the direction perpendicular to the display panel, of a barrier wall proximate to the display area.

16. The display panel according to claim 1, further comprising:
a double-dam located on at least one side of the display area, wherein the single-dam and the double-dam are located on different sides of the display area, and the double-dam includes a first dam body and a second dam body spaced apart from each other; wherein
in a connection region between the single-dam and the double-dam, the single-dam is connected to both the first dam body and the second dam body to form a one-piece structure.

17. The display panel according to claim 16, wherein an edge of the barrier structure is spaced apart from the double-dam.

18. The display panel according to claim 1, further comprising:
a fourth groove located on a side of the single-dam away from the display area.

19. The display panel according to claim 1, wherein in a plane of the display panel, in a direction perpendicular to an extension direction of the second groove, a dimension of the first groove is greater than a dimension of the second groove.

20. A display apparatus, comprising the display panel according to claim 1.
